(19) United States
(12) Patent Application Publication
(10) Pub. No.: US 2007/0070710 A1
(43) Pub. Date: Mar. 29, 2007

(54) Nonvolatile semiconductor memory device and data writing method

(75) Inventor: Tetsuro Takenaka, Miyazaki (JP)

Correspondence Address: NIXON PEABODY, LLP, 401 9TH STREET, NW, SUITE 900, WASHINGTON, DC, 20004-2128, US

(73) Assignee: OKI ELECTRIC INDUSTRY CO., LTD., Tokyo (JP)

(21) Appl. No.: 11/524,279

(22) Filed: Sep. 21, 2006

(30) Foreign Application Priority Data
Sep. 27, 2005 (JP) 2005-279970

(51) Int. Cl. G11C 7/10

(52) U.S. Cl. 365/189.01

(57) ABSTRACT

The present invention aims to eliminate variations in threshold voltage subsequent to the writing of data in an EPROM. When a parasitic resistance between the source of a memory cell (M00) of an even-numbered row and its corresponding bit line (BL0) is larger by a resistance (R00) than a parasitic resistance between the source of a memory cell (M01) of an odd-numbered row and its corresponding bit line (BL0), a cell resistance compensating unit (40) having a compensating resistor (43) whose resistance value is equal to the resistance (R00) is provided between the bit line (BL0) and a ground potential (GND). When the memory cell (M00) is selected by a drain cell power-supply switching address (/AY0), a transistor (41) is turned on by the same signal (/AY0). When the memory cell (M01) is selected by a drain cell power-supply switching address (AY0), a transistor (42) is turned on by the same signal (AY0). The resistor (43) is inserted for the transistor (42), and resistance values from the sources of the memory cells (M00, M01) to the ground potential (GND) become equal to each other. Thus, variations in threshold voltage subsequent to the writing of data can be suppressed.

### BACKGROUND OF THE INVENTION

The present invention relates to a nonvolatile semiconductor memory device (hereinafter called “EPROM”) capable of electrically writing data, and particularly to an improvement in data writing accuracy thereof and a data writing method thereof.

FIG. 2 is a schematic configurational diagram of a conventional or prior art EPROM.

The EPROM is equipped with a memory array 10, a column switch unit 20 and a write driver 30.

The memory array 10 is one of such a type that MOS transistors having floating gates for storing electric charges are used as memory cells and the memory cells are arranged in matrix form. The memory array 10 has selector lines SL0, SL1 and SL2 disposed in parallel, and bit lines BL0 and BL1 disposed in parallel between these selector lines SL0 and SL2. Further, the memory array 10 has a plurality of word lines WLi (where i=0 to n) disposed so as to be orthogonal to the selector lines SL0 through SL2 and the bit lines BL0 and BL1.

Memory cells Mi0 are connected between the adjacent selector line SL0 and bit line BL0 in association with the respective word lines WLi. The drains of the memory cells Mi0 are connected to the selector line SL0, the sources thereof are connected to the bit line BL0, and their control gates are connected to the word lines WLi, respectively. Memory cells Mi1 are connected between the selector line SL1 and the bit line BL0. The drains of the memory cells Mi1 are connected to the selector line SL1, the sources thereof are connected to the bit line BL0, and their control gates are connected to the word lines WLi, respectively.

Similarly, memory cells Mi2 are connected between the selector line SL1 and the bit line BL1. The drains of the memory cells Mi2 are connected to the selector line SL1, the sources thereof are connected to the bit line BL1, and their control gates are connected to the word lines WLi, respectively. Further, memory cells Mi3 are connected between the selector line SL2 and the bit line BL1. The drains of the memory cells Mi3 are connected to the selector line SL2, the sources thereof are connected to the bit line BL1, and their control gates are connected to the word lines WLi, respectively.

The selector lines SL0 and SL2 are connected to a drain power supply VCD via transistors (hereinafter called “TRs”) 11 and 13, and the selector line SL1 is connected thereto via a TR 12, respectively. The TRs 11 and 13 and the TR 12 are respectively on/off-controlled by complementary cell drain power-supply switching addresses /AY0 and AY0.

Incidentally, resistors R connected in series with the memory cells M are not formed as resistive elements but are indicative of parasitic resistance components based on the memory cells M and wirings or the like although they will be described in detail later. Likewise, resistors Rs described in the selector lines SLs and resistors Rb described in the bit lines BLs are not formed as resistive elements but are indicative of ones that intensively show wiring resistances of these selector lines SLs and bit lines BLs.

The column switch unit 20 is constituted of TRs 21 and 22. The drains of these TRs 21 and 22 are respectively connected to the bit lines BL0 and BL1, whereas the sources thereof are respectively connected to a node N20. The gates of the TRs 21 and 22 are respectively supplied with complementary column select addresses /AY1 and AY1, and the TRs 21 and 22 are respectively on/off-controlled by the column select addresses /AY1 and AY1 on a complementary basis.

The write driver 30 comprises a TR 31 of which the drain and source are respectively connected to the node N20 and a ground potential GND and the gate is supplied with write data /DATA from an unillustrated data line.

FIG. 3 is a layout diagram showing part of the memory array shown in FIG. 2.

FIG. 3 typically shows the layout of the selector lines SL0 and SL1, bit lines BL0 and BL1 and word line WL0 which connect the memory cells M00, M01, M02 and M03 with these memory cells as the center.

Control gates G of the respective memory cells M00 through M03 are commonly connected to their corresponding word line WL0 extending in a transverse direction as viewed in the drawing. The drains D of the memory cells M00 and M02 are respectively connected via contacts C to the selector lines SL0 and SL1 formed on an unillustrated insulating layer in a vertical direction as viewed in the drawing. The sources S of the memory cells M00 and M02 are respectively connected to the sources S of the memory cells M01 and M03 adjacent thereto through activation of polysilicon or the like. The sources S of the memory cells M01 and M03 are respectively connected via contacts C to the bit lines BL0 and BL1 formed on the insulating layer in parallel with the selector lines. Further, the drains D of the memory cells M01 and M03 are respectively connected to the drains D of the memory cells M02 and M04 adjacent thereto through activation in polysilicon or the like.

With such a structure, parasitic resistances that exist between the sources S of the memory cells M00 and M02 of even-numbered rows and the bit lines BL0 and BL1 respectively increase because they remain active long, as compared with parasitic resistances existing between the drains D thereof and the selector lines SL0 and SL1. On the other hand, parasitic resistances that exist between the drains D of the memory cells M01 and M03 of odd-numbered rows and the selectors lines SL1 and SL2 respectively increase because they remain active long, as compared with parasitic resistances that exist between the sources S thereof and the bit lines BL0 and BL1. Incidentally, resistors R00 and R02 shown on the source sides of the memory cells M00 and M02 of even-numbered rows are respectively indicative of resistance differences obtained by subtracting parasitic resistances on the drain sides from parasitic resistances on the source sides. Resistors R01 and R03 shown on the drain sides of the memory cells M01 and M03 of odd-numbered rows are respectively indicative of resistance differences obtained by subtracting parasitic resistances on the source sides from parasitic resistances on the drain sides.

FIG. 4 is a flowchart showing a data writing procedure of the conventional EPROM.

The EPROM is set to an EPROM write device and a predetermined source voltage is applied to check for voltages and currents at respective terminals. A contact check as to whether the EPROM has been reliably set is made. If an error exists, then a contact error display is carried out. If it is found that the EPROM has been set properly, then a 0 address for a write start is set and a standard write source voltage designated to the EPROM is set. Thereafter, the writing of data is performed and addresses are sequentially changed until the execution of writing at the final address to continue to do writing. Then, data at the final address is written and thereby data writing is ended.

However, the following problems occur in the EPROM of FIG. 2 where the data writing is made thereto in such a procedure as shown in FIG. 4.

That is, a write source voltage is always held as a constant value regardless of write addresses in the procedure of FIG. 4. On the other hand, when a memory cell (e.g., M00) of an even-numbered row is selected in the EPROM of FIG. 2 and a memory cell (e.g., M01) of an odd-numbered row is selected in the EPROM, the values of resistances from the sources of these memory cells and a ground potential GND are different from each other. Therefore, currents that flow when the same write source voltage is applied are different from each other. Hence, there is a fear that the threshold voltages of the post-writing memory cells are different from each other in terms of the odd-numbered and even-numbered rows, thus causing an error upon reading.

The inventions for avoiding such problems have been described in patent documents 1 (Japanese Unexamined Patent Publication No. Hei 11(1999)-110991) and 2 (Japanese Unexamined Patent Publication No. 2003-51193).

FIG. 5 is a configurational diagram of a conventional semiconductor memory device described in the patent document 1.

The semiconductor memory device is equipped with a circuit for preventing that cell currents vary due to the fact that diffused resistances or the like take values different between memory cells, thereby degrading reading accuracy, in some cases, causing a malfunction. That is, the semiconductor memory device has a decision current control circuit 1 which controls the amount of a decision current Io (m) so as to correct a variation in bit line current IR (m) subsequent to the reading of a memory cell Mm, which is developed by a difference in resistance between the memory cell and a common voltage supply line SSL, prior to the reading of the memory cell Mm to thereby allow it to flow through a bit line BLm. The decision current control circuit 1 has a series resistive body 2 in which a plurality of resistors are connected in series, and selection transistors ST1 and ST2 which are connected to at least one terminals thereof and connect the series resistive body 2 to a decision voltage supply line PCL according to the application of a control signal. Each connecting node of the resistors of the series resistive body 2 is connected to the bit line BLm at which the value of a resistance from the connecting node to the decision voltage supply line PCL becomes approximately identical to the value of a resistance from each memory cell to the common voltage supply line SSL.

Thus, the series resistive body 2 is inserted between the bit line BLm and the decision voltage supply line PCL with respect to the difference between the diffused resistances or the like of the memory cell Mm to correct a variation in the post-reading bit line current IR (m), thereby making it possible to enhance the accuracy of reading of data.

Described in the patent document 2 is a semiconductor device such as a flash memory or the like configured in such a manner that in order to suppress variations in threshold-voltage shift amount of each bit at writing/erasure, an area (user area) in which a user is able to obtain access to within a memory array and an area (test area) in which the user is not able to obtain access thereto, are provided, and trimming data for applied voltages at writing/erasure in the user area are held in the test area in address units.

The semiconductor device is equipped with a latch circuit which latches the trimming data read from the test area in accordance with write/erase addresses, a logic circuit which generates a limit voltage, based on the trimming data of the latch circuit, a limiter circuit which generates a control signal, based on the limit voltage, a step-up circuit which generates a write/erase voltage, based on the control signal, and a power switching circuit which performs switching to the write/erase voltage.

When the write/erase addresses are inputted, the test area is read in accordance with the addresses and trimming data at writing/erasure, of its corresponding user area is retained in the latch circuit. The trimming data held in the latch circuit is supplied to the logic circuit to generate a limit voltage. A control signal is generated based on the limit voltage. Further, a write/erase voltage is generated based on the control signal and supplied to the corresponding memory cell. Thus, the write/erase voltage is adjusted for every address and hence the variations in threshold-voltage shift amount of each bit at the writing/erasure can be eliminated.

However, the semiconductor memory device described in the patent document 1 is accompanied by a problem that the accuracy of data reading is enhanced by correcting the variation in the post-reading bit line current IR (m), whereas adaptation to variations in threshold voltage at the writing of data in the EPROM cannot be performed.

Further, the semiconductor device described in the patent document 2 is accompanied by a problem that in order to adjust the write/erase voltage in units of addresses, the test area is provided within the memory array and the latch circuit, logic circuit and limiter circuit are needed, thus increasing a circuit scale.

### SUMMARY OF THE INVENTION

With the foregoing in view, it is an object of the present invention to eliminate variations in threshold voltage subsequent to the writing of data in an EPROM.

According to one aspect of the present invention, for attaining the above object, there is provided an EPROM including selector lines and bit lines alternately disposed in parallel, a plurality of word lines disposed so as to intersect with the selector lines and the bit lines, and nonvolatile memory cells provided at respective intersecting points of the selector and bit lines and the word lines and disposed in matrix form in such a manner that drains and sources thereof are respectively connected to the selector lines and the bit lines and control gates thereof are respectively connected to the word lines, wherein when a memory cell of an ith (where i: positive integer) row is selected, the value of a first parasitic resistance from a source of the selected memory cell to its corresponding bit line is larger than the value of a second parasitic resistance from a source of a memory cell of an i+1th row to its corresponding bit line when the memory cell of i+1th row is selected, the EPROM comprising cell resistance compensating means which connects the bit line to a ground potential when data is written into the memory cell of the ith row, and connects the bit line to the ground potential via a resistance corresponding to a difference between the first and second parasitic resistances when data is written into the memory cell of i+1th row.

The present invention is provided with cell resistance compensating means that when the values of parasitic resistances from the sources of memory cells of ith and i+1th rows to their corresponding bit lines are different from one another, selectively inserts a resistance corresponding to the difference between the parasitic resistances upon data writing to thereby compensate for the values of resistances of paths extending from the sources to a ground potential via the bit lines such that their values become the same value. Thus, an advantageous effect is brought about in that the values of write currents for the memory cells become uniform and hence variations in threshold voltage subsequent to the data writing can be eliminated.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a configurational diagram of an EPROM showing a first embodiment of the present invention;

FIG. 2 is a schematic configurational diagram of a conventional EPROM;

FIG. 3 is a layout diagram showing part of a memory array in FIG. 2;

FIG. 4 is a flowchart illustrating a data writing procedure of the conventional EPROM;

FIG. 5 is a configurational diagram of a conventional semiconductor memory device;

FIG. 6 is a configurational diagram of an EPROM showing a second embodiment of the present invention;

FIG. 7 is a configurational diagram of an EPROM illustrating a third embodiment of the present invention;

FIG. 8 is a flowchart of a data writing procedure of an EPROM illustrating a fourth embodiment of the present invention; and

FIG. 9 is a flowchart of a data writing procedure of an EPROM showing a fifth embodiment of the present invention.

### DETAILED DESCRIPTION OF THE PREFERRED EMBODIMENTS

Preferred embodiments of the present invention will hereinafter be described with reference to the accompanying drawings.

When a plurality of memory arrays are connected in parallel with the same bit lines, a bit line resistance compensating means in which a compensating resistor corresponding to the wiring resistance of each bit line connected to the memory array selected from the plurality of memory arrays is inserted therein, is provided between the bit lines and a ground potential in series with a cell resistance compensating means.

### First Preferred Embodiment

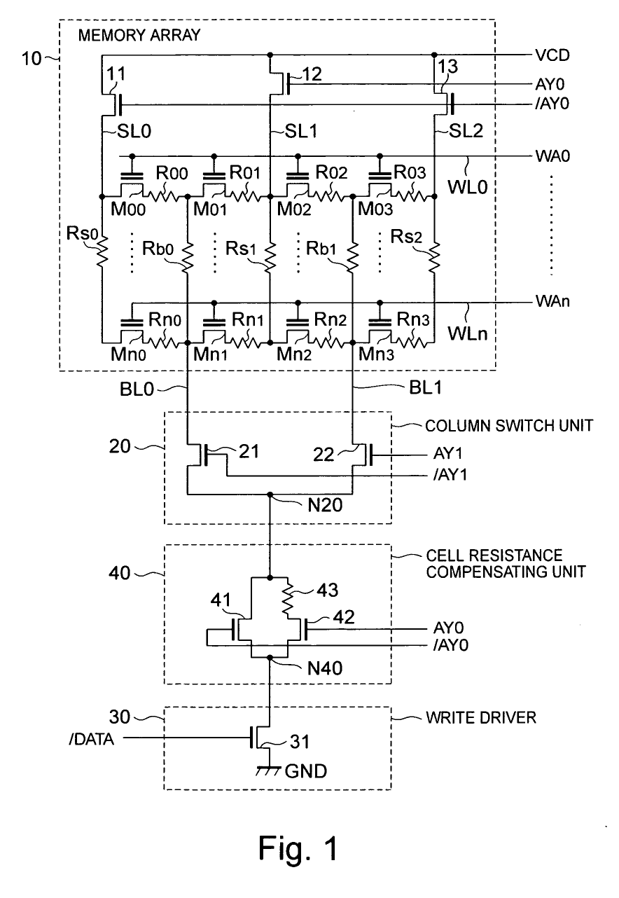

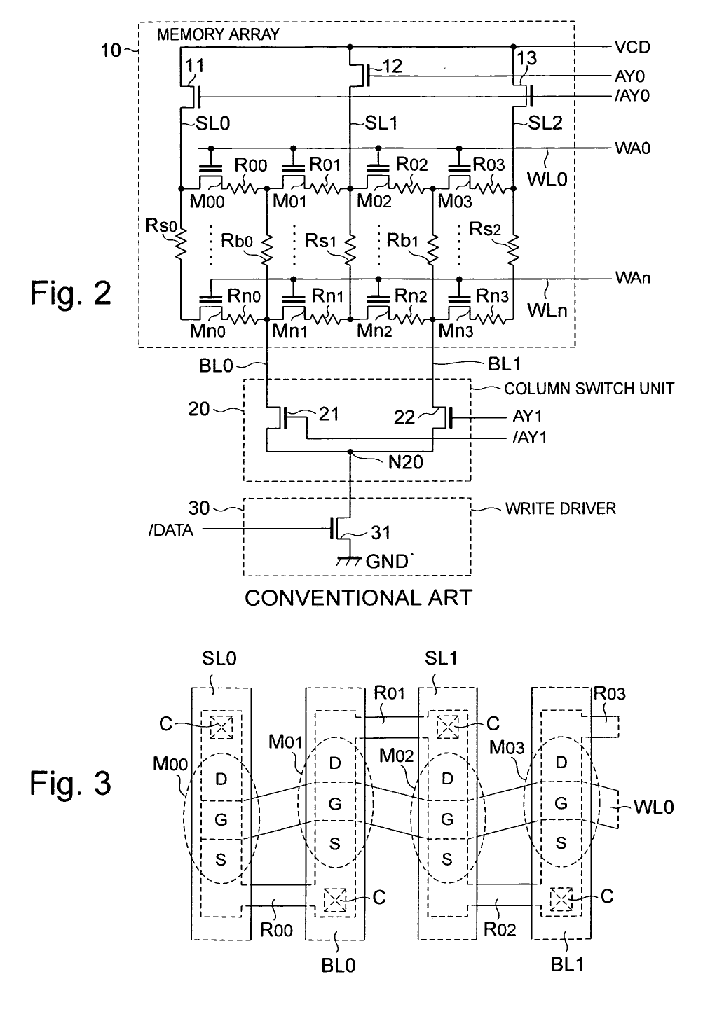

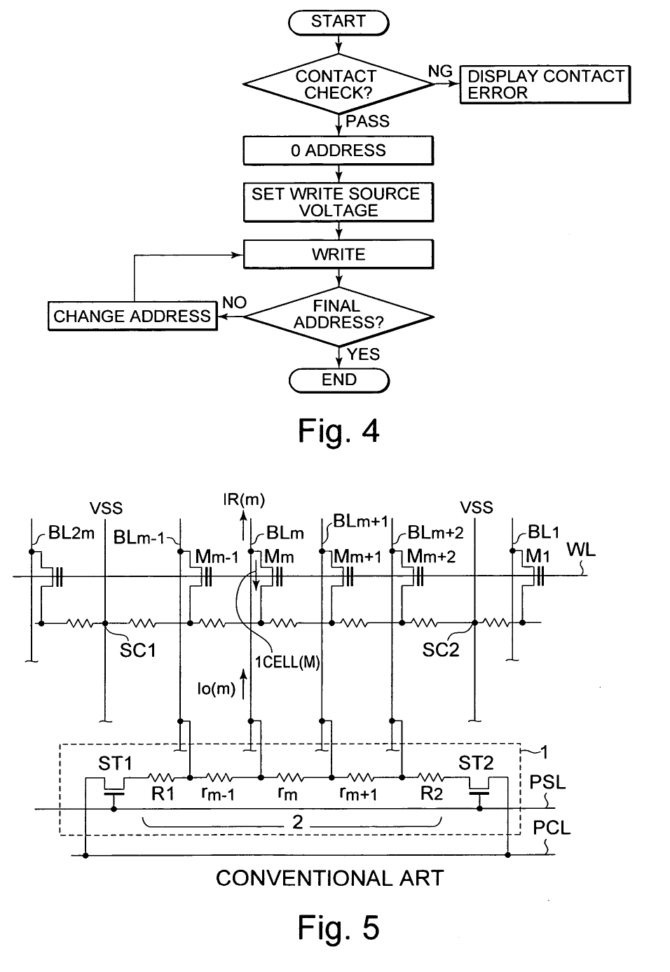

FIG. 1 is a configurational diagram of an EPROM showing a first embodiment of the present invention. Constituent elements common to those shown in FIG. 2 are given common reference numerals respectively.

The EPROM includes a cell resistance compensating unit 40 provided between a column switch unit 20 and a write driver 30 in addition to a memory array 10, the column switch unit 20 and the write driver 30 similar to those shown in FIG. 2.

The memory array 10 is one of such a type that MOS transistors having floating gates for storing electric charges are used as memory cells and the memory cells are arranged in matrix form. The memory array 10 includes selector lines SL0, SL1 and SL2 disposed in parallel, and bit lines BL0 and BL1 disposed in parallel between these selector lines SL0 and SL2. Further, the memory array 10 has a plurality of word lines WLi (where i=0 to n) disposed so as to be orthogonal to the selector lines SL0 through SL2 and the bit lines BL0 and BL1.

Memory cells Mi0 are connected between the adjacent selector line SL0 and bit line BL0 in association with the respective word lines WLi. The drains of the memory cells Mi0 are connected to the selector line SL0, the sources thereof are connected to the bit line BL0, and their control gates are connected to the word lines WLi, respectively. Memory cells Mi1 are connected between the selector line SL1 and the bit line BL0. The drains of the memory cells Mi1 are connected to the selector line SL1, the sources thereof are connected to the bit line BL0, and their control gates are connected to the word lines WLi, respectively.

Likewise, memory cells Mi2 are connected between the selector line SL1 and the bit line BL1. The drains of the memory cells Mi2 are connected to the selector line SL1, the sources thereof are connected to the bit line BL1, and their control gates are connected to the word lines WLi, respectively. Further, memory cells Mi3 are connected between the selector line SL2 and the bit line BL1. The drains of the memory cells Mi3 are connected to the selector line SL2, the sources thereof are connected to the bit line BL1, and their control gates are connected to the word lines WLi, respectively.

The selector lines SL0 and SL2 are connected to a drain power supply VCD via TRs 11 and 13, and the selector line SL1 is connected thereto via a TR12, respectively. The TRs 11 and 13 and the TR 12 are on/off-controlled on a complementary basis by complementary cell drain power-supply switching addresses /AY0 and AY0.

Incidentally, resistors R connected in series with the memory cells M are not formed as resistive elements but are indicative of parasitic resistance components based on the memory cells M and wirings. That is, the parasitic resistances that exist between the sources S of the memory cells M00 and M02 or the like corresponding to even-numbered rows and their corresponding bit lines BL0 and BL1 increase because they are held active long, as compared with the parasitic resistances between the drains D thereof and the selector lines SL0 and SL1 in terms of a layout configuration of the selector lines SLs, bit lines BLs and memory cells Ms. Accordingly, resistors R00, R02 and the like connected to the source sides of the memory cells M00, M02 and the like are respectively equivalent to resistance differences obtained by subtracting parasitic resistances on the drain sides from parasitic resistances on the source sides. //On the other hand, parasitic resistances that exist between the drains D of the memory cells M01 and M03 of odd-numbered rows and the selector lines SL1 and SL2 become large because they remain active long, as compared with parasitic resistances that exist between the sources S and the bit lines BL0 and BL1. Accordingly, resistors R01, R03 and the like shown on the drain sides of the memory cells M01, M03 and the like of odd-numbered rows are respectively equivalent to resistance differences obtained by subtracting parasitic resistances on the source sides from parasitic resistances on the drain sides.

Incidentally, the values of these resistors R00 and like become approximately the same value (e.g., about 500Ω) because the respective memory cells M are formed with the same size and material. Resistors shown in the selector lines SLs and resistors shown in the bit lines BLs result in ones which intensively show wiring resistances of these selector lines SLs and bit lines BLs without forming the same as resistive elements.

The column switch unit 20 is constituted of TRs 21 and 22. The drains of these TRs 21 and 22 are respectively connected to the bit lines BL0 and BL1, whereas the sources thereof are respectively connected to a node N20. The gates of the TRs 21 and 22 are respectively supplied with complementary column select addresses /AY1 and AY1, and hence the TRs 21 and 22 are respectively on/off-controlled by the column select addresses /AY1 and AY1 on a complementary basis.

The cell resistance compensating unit 40 is one of such a type that when the memory cells M01, M03 and the like corresponding to the odd-numbered rows, i.e., such memory cells that the parasitic resistances existing between their sources and the bit lines BLs become small are selected, a compensating resistor is inserted in a path for a writing bit line current. The cell resistance compensating unit 40 comprises TRs 41 and 42 and a compensating resistor 43. The drain of the TR 41 is connected to the node N20 of the column switch unit 20. The drain of the TR 42 is connected to the node N20 via the resistor 43. The sources of the TRs 41 and 42 are commonly connected to a node N40. These TRs 41 and 42 are supplied with their corresponding complementary cell drain power-supply switching addresses /AY0 and AY0 at their sources and on/off-controlled by them on a complementary basis.

Incidentally, the resistor 43 is adjusted in size in such a manner that its resistance value becomes approximately the same value as the value of the resistor R00 or the like in the memory cell 10. The resistor 43 is formed under activation of the same material (for example, polysilicon or the like) as the memory cell M00 or the like.

The write driver 30 comprises a TR 31 of which the drain and source are respectively connected to the node N40 and a ground potential GND and the gate is supplied with write data /DATA from an unillustrated data line.

A data write operation of the EPROM will next be explained.

When writing is performed on a memory cell (e.g., M00) of an even-numbered row, a write high voltage is applied to the power supply VCD and the word line WL0, and the cell drain power-supply switching address /AY0, the column select address /AY1 and the write data /DATA are respectively set to a level “H”. At this time, the word lines WL1 through WLn, the cell drain power-supply switching address AY0 and the column select address AY1 are respectively a level “L”. Thus, a resistance R (M00) from the source of the memory cell M00 to the ground potential GND is as follows:
R(M00)=R00+Rb0+On Resistance of TR21+On Resistance of TR41+On Resistance of TR31

On the other hand, when writing is effected on a memory cell (e.g., M01) corresponding to an odd-numbered row, a write high voltage is applied to the power supply VCD and the word line WL0, and the cell drain power-supply switching address AY0, the column select address /AY1 and the write data /DATA are respectively set to “H”. At this time, the word lines WL1 through WLn, the cell drain power-supply switching address /AY0 and the column select address AY1 are respectively “L”. Thus, a resistance R (M01) from the source of the memory cell M01 to the ground potential GND is as follows:
R(M01)=Rb0+On Resistance of TR21+R43+On Resistance of TR42+On Resistance of TR 31
Since the on resistance of TR 41 is equal to the on resistance of the TR 42 and R43 is set so as to be equal to R00 here, R (M00)=R (M01). Thus, there is no resistance difference developed due to the difference in layout between the memory cell of the even-numbered row and the memory cell of the odd-numbered row.

As described above, the EPROM of the first embodiment brings about an advantage that since it has the cell resistance compensating unit 40 for compensating for the resistance difference developed due to the difference in layout between the memory cells of the even-numbered and odd-numbered rows, variations in post-writing threshold voltage can be suppressed.

### Second Preferred Embodiment

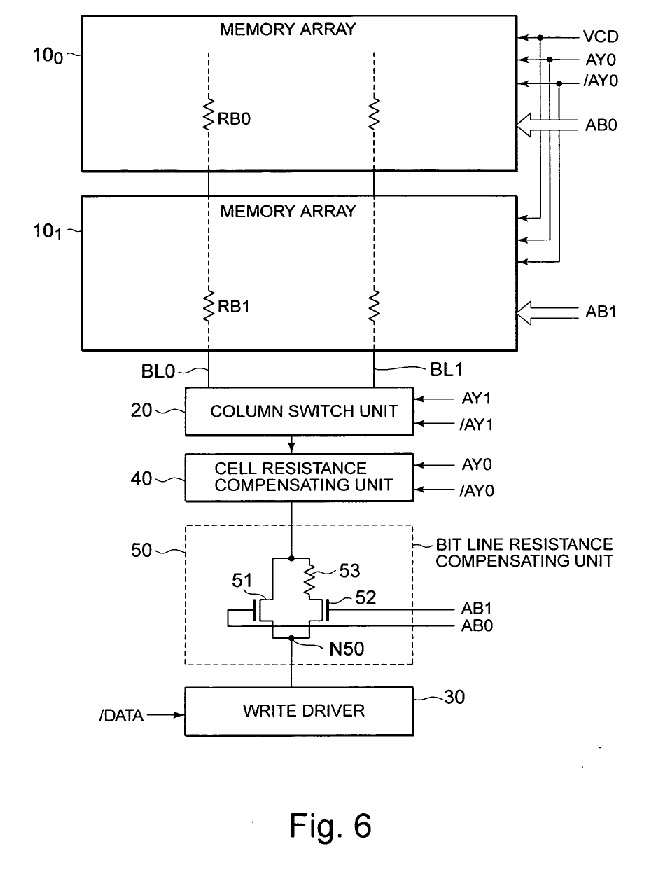

FIG. 6 is a configurational diagram of an EPROM showing a second embodiment of the present invention. Constituent elements common to the constituent elements shown in FIG. 1 are given common reference numerals respectively.

The EPROM includes a bit line resistance compensating unit 50 provided between a cell resistance compensating unit 40 and a write driver 30 in addition to two sets of memory arrays 10₀ and 10₁, a column switch unit 20, the drive driver 30 and the cell resistance compensating unit 40.

Each of the memory arrays 10₀ and 10₁ has a configuration similar to the memory array 10 shown in FIG. 1. The memory arrays 10₀ and 10₁ share bit line BL0 and BL1 and have individual or discrete selector lines SL0, SL1 and SL2. These memory arrays 10₀ and 10₁ are respectively exclusively selected by select signals AB0 and AB1 supplied to word lines WL0 through WLn.

The bit line resistance compensating unit 50 is one of such a type that when a memory array (memory array 10₁ in the case shown in the present drawing) small in bit line wiring resistance is selected, a compensating resistor is inserted in a writing bit line current path. The bit line resistance compensating unit 50 comprises TRs 51 and 52 and a compensating resistor 53. The drain of the TR 51 is directly connected to the output side of the cell resistance compensating unit 40 and the drain of the TR 52 is connected thereto via a resistor 53, respectively. The sources of the TRs 51 and 52 are commonly connected to a node N50. The gate of the TR 51 is supplied with a select signal AB0 for the memory array 100, and the gate of the TR 52 is supplied with a select signal AB1 for the memory array 10₁. Thus, the TRs 51 and 52 are exclusively on/off-controlled by the select signals AB0 and AB1. Incidentally, the resistor 53 is formed of polysilicon or the like adjusted in size in such a manner that the resistance value R53 of the resistor 53 becomes approximately equal to the resistance value of a bit line wiring resistor RB1 of the memory array 10₁ added in between when the memory array 10₀ is selected.

A data write operation of the present EPROM will next be explained.

When writing is performed on a memory cell (e.g., M00) of the memory array 10₀, a write high voltage is applied to a power supply VCD and the word line WL0 of the memory array 10₀, and a cell drain power-supply switching address /AY0, a column select address /AY1, the select signal AB0 and write data /DATA are respectively set to “H”. At this time, the word lines WL1 through WLn of the memory array 10₀, a cell drain power-supply switching address AY0, a column select address AY1 and a select signal AB1 are respectively “L”. Thus, a resistance R (M00₀) from the source of the memory cell M00 of the memory array 10₀ to a ground potential GND is as follows:
R(M00₀)=R00+RB0+On Resistance of TR21+On Resistance of TR41+On Resistance of TR51+On Resistance of TR31

On the other hand, when writing is effected on a memory cell (e.g., M00) of the memory array 10₁, a write high voltage is applied to the power supply VCD and the word line WL0 of the memory array 10₁, and the cell drain power-supply switching address /AY0, column select address /AY1, select signal AB1 and write data /DATA are respectively set to “H”. At this time, the word lines WL1 through WLn of the memory array 10₁, the cell drain power-supply switching address AY0 and the column select address AY1 and the select signal AB0 are respectively “L”. Thus, a resistance R (M00₁) from the source of the memory cell MOO of the memory array 10₁ to the ground potential GND is as follows:
R(M00₁)=R00+RB1+On Resistance of TR21+On Resistance of TR41+R53+On Resistance of TR51+On Resistance of TR31

Since RB0 and RB1 are approximately the same value and R53 is set to the same value as RB1 here, R (M00₀)=R (M00₁). Thus, there is no resistance difference developed due to the difference in layout between the memory array 10₀ and the memory array 10₁.

As described above, the EPROM of the second embodiment brings about an advantage that since it has the bit line resistance compensating unit 50 for compensating for the resistance difference between the bit lines, which is developed due to the difference in layout between the plural memory arrays, where it has the plurality of memory arrays, variations in post-writing threshold voltage can be suppressed.

### Third Preferred Embodiment

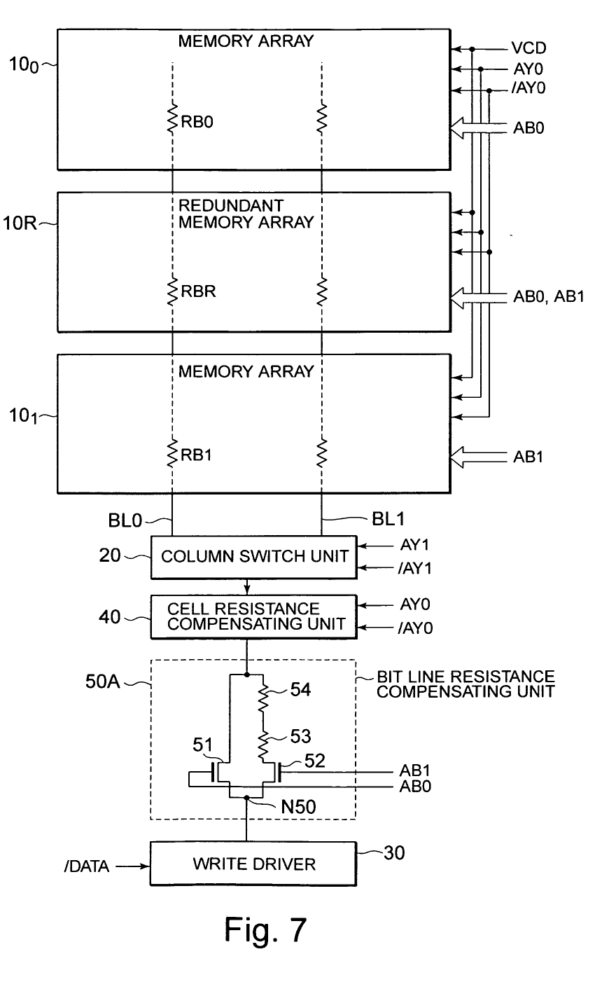

FIG. 7 is a configurational diagram of an EPROM showing a third embodiment of the present invention. Constituent elements common to the constituent elements shown in FIG. 6 are given common reference numerals respectively.

The EPROM includes a bit line resistance compensating unit 50A provided between a cell resistance compensating unit 40 and a write driver 30 in addition to two sets of memory arrays 10₀ and 10₁, a redundant memory array 10R, a column switch unit 20, the drive driver 30 and the cell resistance compensating unit 40.

Any of the memory arrays 10₀ and 10₁ and the redundant memory array 10R has a configuration similar to the memory array 10 shown in FIG. 1. They share bit line BL0 and BL1 and have individual or discrete selector lines SL0, SL1 and SL2. Incidentally, the redundant memory array 10R is disposed between the memory arrays 10₀ and 10₁. When either one of the memory arrays 10₀ and 10₁ is defective, the redundant memory array 10R is selected in place of the defective memory array 10₀ or 10₁.

The bit line resistance compensating unit 50A is one of such a type that a resistor 54 is connected in series with the resistor 53 in FIG. 6. A resistance value R54 of the resistor 54 is set so as to be approximately equal to a resistance value RBR of each bit line in the redundant memory array 10R.

In the present EPROM, a resistance R (M00₀) from the source of a memory cell M00 of the memory array 100 to a ground potential GND at the time that the memory cell M00 thereof is selected, is as follows:
R(M00₀)=R00+RB0+RBR+RB1+On Resistance of TR21+On Resistance of TR41+On Resistance of TR51+On Resistance of TR31

On the other hand, when a memory cell M00 of the redundant memory array 10R is selected as an alternative to the memory array 100, a resistance R (M00₀R) from its source to the ground potential GND is as follows:
R(M00₀R)=R00+RBR+RB1+On Resistance of TR21+On Resistance of TR41+On Resistance of TR51+On resistance of TR31.

Thus, when the redundant memory array 10R is selected as a substitute for the memory array 10₀, the resistance corresponding to RB0 is reduced.

When a memory cell M00 of the memory array 10₁ is selected, a resistance R (M00₁) from its source to the ground potential GND is as follows:
R(M00₁)=R00+RB1+On Resistance of TR21+On Resistance of TR41+R54+R53+On Resistance of TR51+On Resistance of TR31

Further, when the memory cell M00 of the redundant memory array 10R is selected as an alternative to the memory array 10, a resistance R (M00₁R) from its source to the ground potential GND is as follows:
R(M00₁R)=R00+RBR+RB1+On Resistance of TR21, On Resistance of TR41+R54+R53+On Resistance of TR51+On Resistance of TR31

Thus, when the redundant memory array 10R is selected as a substitute for the memory array 10₁, the resistance corresponding to RBR is increased.

As mentioned above, the EPROM according to the third embodiment has the bit line resistance compensating unit 50A for compensating for the difference in resistance between the bit lines developed due to the difference in layout between the plurality of memory arrays and the redundant memory array where it has the plurality of memory arrays and the redundant memory array. Thus, the EPROM brings about an advantage in that even when the redundant memory array is selected, the difference in resistance between the bit lines can be suppressed to a range corresponding to one memory array, and variations in post-writing threshold voltage can be suppressed.

### Fourth Preferred Embodiment

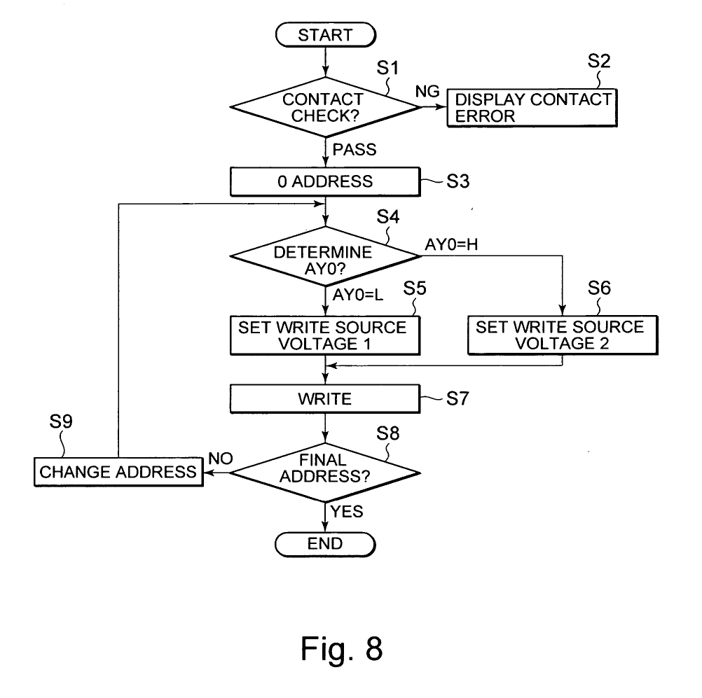

FIG. 8 is a flowchart of a data writing procedure of an EPROM showing a fourth embodiment of the present invention.

The data writing procedure intends to perform writing in such a way as to suppress variations in threshold voltage subsequent to the writing of data into the EPROM of FIG. 2. The data writing procedure is a technique for incorporating it in a PROM write device as hardware or using it in a PROM tester or the like as a writing program.

The data writing procedure will be explained below using FIG. 8.

At Step S1, the EPROM is set to an EPROM write device and a predetermined power supply voltage is applied thereto to check for voltages and currents at respective terminals. Then, a contact check is made as to whether the EPROM is reliably set. If an error occurs, then the data writing procedure proceeds to Step S2. If it is found to be normal, then the data writing procedure proceeds to Step S3.

At Step S2, a contact error display is made to urge the EPROM to be reset properly.

At Step S3, the data writing procedure sets a 0 address for a write start and proceeds to Step S4.

It is determined at Step S4 whether a cell drain power-supply switching address AY0 corresponding to a write address is “L” or “H”. If the cell drain power-supply switching address AY0 is found to be “L”, then the data writing procedure proceeds to Step S5. If the cell drain power-supply switching address AY0 is found to be “H”, then the data writing procedure proceeds to Step S6.

At Step S5, the data writing procedure sets a write source voltage 1 used as the reference and proceeds to Step S7. At Step S6, a source voltage 2 slightly lower than the source voltage 1 is set in such a manner that a write current is restricted by one equivalent to the resistor 43 of the cell resistance compensating unit 40 shown in FIG. 1. At Steps S5 and S6, the data writing procedure sets source voltages each used for compensating for a resistance difference developed due to the difference in layout between memory cells and thereafter proceeds to Step S7.

At Step S7, the data writing procedure performs writing of data using the source voltages set at Steps S5 and S6 and proceeds to Step S8.

At Step S8, a decision as to whether data writing at a final address has been performed is made. If the writing of data at the final address is found to have been completed, then write processing is completed. If the data writing at the final address is found not to have been completed, then the data writing procedure proceeds to Step S9.

At Step S9, a write address is updated or renewed and the data writing procedure is returned to Step S4, where the processes from Steps S4 to S9 are repeated until the writing at the final address is ended.

In the data writing method of the EPROM according to the fourth embodiment as described above, the write source voltage 1 defined as the reference and the write source voltage 2 for compensating for the difference in active or contact resistance, for example, developed due to the difference in layout between the drain and source of each memory cell are used. These source voltages 1 and 2 are switched in accordance with address determination. Thus, an advantage is brought about in that variations in threshold voltage subsequent to the writing of data into the EPROM can be suppressed.

### Fifth Preferred Embodiment

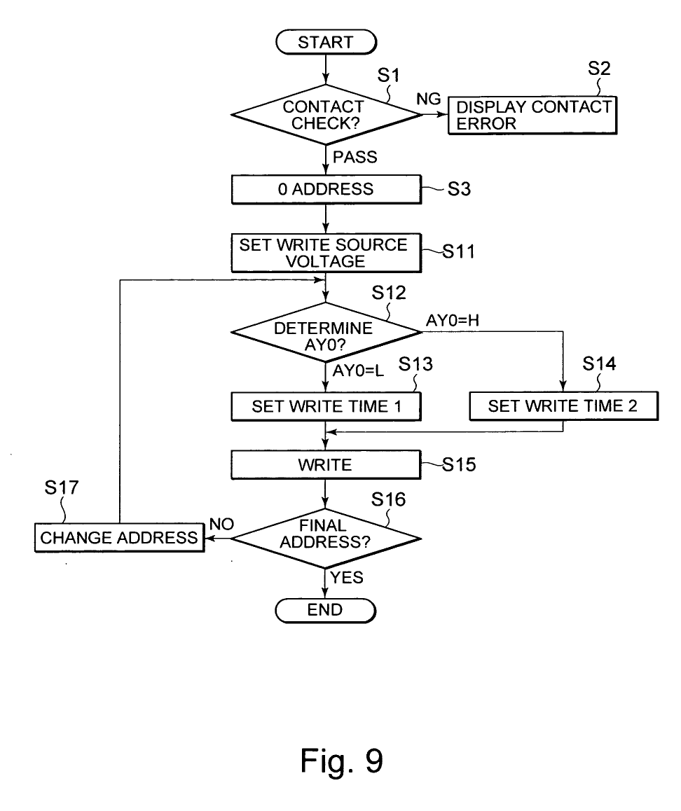

FIG. 9 is a flowchart of a data writing procedure of an EPROM showing a fifth embodiment of the present invention. Constituent elements common to those shown in FIG. 8 are given common reference numerals respectively.

The data writing procedure intends to perform writing in such a way as to suppress variations in threshold voltage subsequent to the writing of data into the EPROM of FIG. 2 in a manner similar to FIG. 8. The data writing procedure is a technique for incorporating it in a PROM write device as hardware or using it in a PROM tester or the like as a writing program.

At Step S1, the EPROM is set to an EPROM write device and a contact check is made. If an error is found to have occurred, then a contact error display is carried out at Step S2. If the EPROM is found to have been set properly, then processing up to the setting of a 0 address for a write start at Step S3 is similar to FIG. 8.

After Step S3, the data writing procedure proceeds to Step S11, where a standard write power supply or source voltage is set. After Step S11, the data writing procedure proceeds to Step S12.

It is determined at Step S12 whether a cell drain power-supply switching address AY0 corresponding to a write address is “L” or “H”. If the cell drain power-supply switching address AY0 is found to be “L”, then the data writing procedure proceeds to Step S13. If the cell drain power-supply switching address AY0 is found to be “H”, then the data writing procedure proceeds to Step S14.

At Step S13, the data writing procedure sets a write time 1 used as the reference and proceeds to Step S15. At Step S14, a write time 2 slightly shorter than the write time 1 is set in such a manner that a write time is restricted by one equivalent to the resistor 43 of the cell resistance compensating unit 40 shown in FIG. 1. At Steps S13 and S14, the write times each used for compensating for a resistance difference developed due to the difference in layout between memory cells are set and thereafter the data writing procedure proceeds to Step S15.

At Step S15, the data writing procedure performs writing of data using the write times set at Steps S13 and S14 and proceeds to Step S16.

At Step S16, a decision as to whether data writing at a final address has been performed is made. If the writing of data at the final address is found to have been completed, then write processing is completed. If the data writing at the final address is found not to have been completed, then the data writing procedure proceeds to Step S17.

At Step S17, a write address is updated or renewed and the data writing procedure is returned to Step S12, where the processes from Steps S12 to S17 are repeated until the writing at the final address is ended.

In the data writing method of the EPROM according to the fifth embodiment as described above, the write time 1 defined as the reference and the write time 2 for compensating for the difference in active or contact resistance, for example, developed due to the difference in layout between the drain and source of each memory cell are used. These write times 1 and 2 are switched in accordance with address determination. Thus, an advantage is brought about in that variations in threshold voltage subsequent to the writing of data into the EPROM can be suppressed.

Incidentally, the present invention is not limited to the above embodiments. Various modifications can be made thereto. For example, the following are known as the modifications:

(1) Although the three selectors SLs and the two bit lines BLs are shown in the memory array 10 employed in each of the first to third embodiments, a large number of selector lines and bit lines are actually disposed and the corresponding bit line is to be selected by the column switch unit.

(2) Although the compensating resistor 43 is used in the cell resistance compensating unit 40 employed in each of the first to third embodiments, any one may be used if elements substituted for the resistors are adopted. The on resistance may be controlled by changing the dimensions of TRs 41 and 42 without using the resistors.

(3) The compensating resistors 53 and 54 of the bit line resistance compensating unit 50 employed in the second embodiment and the bit line resistance compensating unit 50A employed in the third embodiment can also be constituted in a manner similar to (2).

(4) Although the EPROM having the two sets of memory arrays are shown in each of the second and third embodiments, the present invention can be applied even to one that has a larger number of memory arrays in like manner.

(5) Although the applied source voltages and the write times are switched by the cell drain power-supply switching address AY0 in each of the fourth and fifth embodiments, the corresponding source voltages and write times may be switched in accordance with combinations of the cell drain power-supply switching address AY0 and the select signals AB0 and AB1 or the like for selecting the memory arrays in the case of an EPROM having a plurality of memory arrays.

What is claimed is:

1. A nonvolatile semiconductor memory device including:
selector lines and bit lines alternately disposed in parallel;
a plurality of word lines disposed so as to intersect with the selector lines and the bit lines; and
nonvolatile memory cells provided at respective intersecting points of the selector and bit lines and the word lines and disposed in matrix form in such a manner that drains and sources thereof are respectively connected to the selector lines and the bit lines and control gates thereof are respectively connected to the word lines,
wherein when a memory cell of an ith (where i: positive integer) row is selected, the value of a first parasitic resistance from a source of the selected memory cell to its corresponding bit line is larger than the value of a second parasitic resistance from a source of a memory cell of an i+1th row to its corresponding bit line when the memory cell of i+1th row is selected, said nonvolatile semiconductor memory device comprising:
cell resistance compensating means which connects the bit line to a ground potential when data is written into the memory cell of the ith row, and connects the bit line to the ground potential via a resistance corresponding to a difference between the first and second parasitic resistances when data is written into the memory cell of i+1th row.

2. A nonvolatile semiconductor memory device including a plurality of memory arrays each comprising:
selector lines and bit lines alternately disposed in parallel;
a plurality of word lines disposed so as to intersect with the selector lines and the bit lines; and
nonvolatile memory cells provided at respective intersecting points of the selector and bit lines and the word lines and disposed in matrix form in such a manner that drains and sources thereof are respectively connected to the selector lines and the bit lines and control gates thereof are respectively connected to the word lines,
wherein when a memory cell of an ith (where i: positive integer) row is selected, the value of a first parasitic resistance from a source of the selected memory cell to its corresponding bit line is larger than the value of a second parasitic resistance from a source of a memory cell of an i+1th row to its corresponding bit line when the memory cell of i+1th row is selected, said nonvolatile semiconductor memory device comprising:
cell resistance compensating means provided between the bit lines and a ground potential and in which a resistance corresponding to a difference between the first and second parasitic resistances is inserted between the bit lines and the ground potential when data is written into the memory cell of i+1th row; and
bit line resistance compensating means provided between the bit lines and the ground potential in series with the cell resistance compensating means and in which a compensating resistance corresponding to a wiring resistance of each bit line connected to a memory array selected from within the plurality of memory arrays is inserted.

3. The nonvolatile semiconductor memory device according to claim 2, wherein one of the plurality of memory arrays is a redundant memory array used as a substitute for a defective memory array lying in the plurality of memory arrays.

4. A method of writing data into a nonvolatile semiconductor memory device including selector lines and bit lines alternately disposed in parallel, a plurality of word lines disposed so as to intersect with the selector lines and the bit lines, and nonvolatile memory cells provided at respective intersecting points of the selector and bit lines and the word lines and disposed in matrix form in such a manner that drains and sources thereof are respectively connected to the selector lines and the bit lines and control gates thereof are respectively connected to the word lines, wherein when a memory cell of an ith (where i: positive integer) row is selected, the value of a first parasitic resistance from a source of the selected memory cell to its corresponding bit line is larger than the value of a second parasitic resistance from a source of a memory cell of an i+1th row to its corresponding bit line when the memory cell of i+1th row is selected, said method comprising:
a process for discriminating whether a memory cell corresponding a data write address belongs to the ith row or the i+1th row;
a process for selecting a first write voltage where the memory cell corresponding to the data write address belongs to the ith row, and selecting a second write voltage lower than the first write voltage where the memory cell belongs to the i+1th row; and
a process for writing data into the memory cell corresponding to the data write address using the selected first or second write voltage,
wherein said processes are executed sequentially.

5. A method of writing data into a nonvolatile semiconductor memory device including selector lines and bit lines alternately disposed in parallel, a plurality of word lines disposed so as to intersect with the selector lines and the bit lines, and nonvolatile memory cells provided at respective intersecting points of the selector and bit lines and the word lines and disposed in matrix form in such a manner that drains and sources thereof are respectively connected to the selector lines and the bit lines and control gates thereof are respectively connected to the word lines, wherein when a memory cell of an ith (where i: positive integer) row is selected, the value of a first parasitic resistance from a source of the selected memory cell to its corresponding bit line is larger than the value of a second parasitic resistance from a source of a memory cell of an i+1th row to its corresponding bit line when the memory cell of i+1th row is selected, said method comprising:
a process for discriminating whether a memory cell corresponding a data write address belongs to the ith row or the i+1th row;
a process for selecting a first write time where the memory cell corresponding to the data write address belongs to the ith row, and selecting a second write time shorter than the first write time where the memory cell belongs to the i+1th row; and
a process for writing data into the memory cell corresponding to the data write address using the selected first or second write time,
wherein said processes are executed sequentially.
